(19) United States
(12) Patent Application Publication
(10) Pub. No.: US 2026/0299025 A1
(43) Pub. Date: Oct. 1, 2026

(54) SYSTEMS AND METHODS FOR END-OF-LIFE (EOL) BATTERY PATHWAY CATEGORIZATION USING A MULTI-CRITERIA DECISION-MAKING ALGORITHM

(71) Applicant: Tata Consultancy Services Limited, Mumbai (IN)

(72) Inventors: Mohammad IMRAN, Chennai (IN); Madhan Mohan PURUSHOTHAMAN, Bangalore (IN); Narasimha Dilip PANCHUMARTHI, Hyderabad (IN); Anil Arvind KUMAR, Nagpur (IN)

(73) Assignee: Tata Consultancy Services Limited, Mumbai (IN)

(21) Appl. No.: 19/553,632

(22) Filed: Mar. 2, 2026

(30) Foreign Application Priority Data
Mar. 25, 2025 (IN) 202521028034

(51) Int. Cl. G01R 31/36; G01R 31/389; G01R 31/392; G05B 13/02

(52) U.S. Cl. CPC G01R 31/3648; G01R 31/389; G01R 31/392; G05B 13/0265

(57) ABSTRACT

A robust circular economy for retired batteries is not just a sustainability goal but an economic and geopolitical necessity. However, conventional methods struggle to accurately identify diverse battery chemistries and degradation levels, limiting reuse potential. The present disclosure addresses the unresolved problems of the conventional methods by providing a system and method for end-of-life (EoL) battery pathway categorization using a multi-criteria decision-making algorithm. The present disclosure leverages X-Ray scanning, battery passport, Electrochemical Impedance Spectroscopy (EIS), Battery Management System (BMS) data analysis, and artificial intelligence (AI) to ensure precise classification of a battery into at least one of a set of end-of life (EoL) battery pathway category using a multi-criteria decision-making algorithm. The multi-criteria decision-making algorithm determines an optimal EoL pathway category from a set of EoL battery pathway categories for the battery when one or more predefined threshold conditions imposed on a set of dominant features are satisfied.

### PRIORITY CLAIM

This U.S. patent application claims priority under 35 U.S.C. § 119 to: India application No. 202521028034, filed on Mar. 25, 2025. The entire contents of the aforementioned application are incorporated herein by reference.

### TECHNICAL FIELD

The disclosure herein generally relates to the field of end-of-life (EoL) battery pathway categorization, and, more particularly, to systems and methods for end-of-life (EoL) battery pathway categorization using a multi-criteria decision-making algorithm.

### BACKGROUND

The global transition toward electric vehicles (EVs) is a pivotal step in achieving carbon neutrality and reducing reliance on fossil fuels. However, this shift introduces a critical challenge which is sustainable management of EV batteries at the end of their lifecycle. EV batteries, predominantly composed of scarce critical metals such as lithium, cobalt, and nickel, are finite resources with highly uneven geographic distribution. Extraction of these materials is concentrated in specific regions, often leading to geo-political tensions and economic vulnerabilities. The increasing demand for EVs exacerbates these issues, making an efficient reuse, recycling, and repurposing of retired batteries an essential economic and environmental imperative. Without a robust circular economic framework, the battery lifecycle risks becoming a linear, wasteful process that contributes to environmental degradation and resource depletion. A poorly managed end-of-life (EOL) strategy for EV batteries could result in significant economic disparities between resource-rich and resource-scarce regions, further intensifying geopolitical dependencies.

Conventional methods struggle to accurately identify diverse battery chemistries and degradation levels, limiting reuse potential. Existing systems rely heavily on manual or semi-automated processes, leading to inefficiencies and inaccuracies in sorting batteries by chemistry, state of health, or usability. Further, the high implementation costs of existing systems prevent widespread adoption, particularly in developing regions. Consequently, developing sustainable, scalable, and accurate methods to sort and manage EOL batteries is crucial to unlocking full value of a battery ecosystem while reducing environmental harm and mitigating economic inequalities.

### SUMMARY

Embodiments of the present disclosure present technological improvements as solutions to one or more of the above-mentioned technical problems recognized by the inventors in conventional systems. For example, in one embodiment, a processor implemented method is provided. The processor implemented method, comprising: receiving, via one more hardware processors, a plurality of aggregated data pertaining a plurality of recyclable batteries in a battery sorting facility, wherein the plurality of aggregated data comprises at least (i) a plurality of diagnostic data acquired using one or more diagnostic tools, (ii) a plurality of vision data acquired using one or more image acquisition devices and one or more sensors, (ii) a plurality of battery performance data acquired using Electrochemical Impedance Spectroscopy (EIS), and (iv) a plurality of battery passport data; preprocessing, via the one more hardware processor, the plurality of aggregated data using one or more preprocessing techniques to obtain a plurality of preprocessed data; inputting, via the one more hardware processor, the plurality of preprocessed data to an adaptive artificial intelligence (AI) model to obtain a plurality of trained data; extracting, via the one more hardware processors, a plurality of features from the plurality of trained data using one or more feature extraction techniques; identifying, via the one more hardware processors, a set of dominant features from the plurality of features based on a weighted score assigned to each of the plurality of features; and classifying, via the one more hardware processors, the set of dominant features from the plurality of features into at least one set of end-of-life (EoL) battery pathway category using a multi-criteria decision-making algorithm, wherein the multi-criteria decision-making algorithm determines an optimal EoL pathway category from the set of end-of life (EoL) battery pathway categories for each of the plurality of recyclable batteries when one or more predefined threshold conditions imposed on the set of dominant features are satisfied.

In another aspect, a system is provided. The system comprising a memory storing instructions; one or more communication interfaces; and one or more hardware processors coupled to the memory via the one or more communication interfaces, wherein the one or more hardware processors are configured by the instructions to: receive a plurality of aggregated data pertaining a plurality of recyclable batteries in a battery sorting facility, wherein the plurality of aggregated data comprises at least (i) a plurality of diagnostic data acquired using one or more diagnostic tools, (ii) a plurality of vision data acquired using one or more image acquisition devices and one or more sensors, (ii) a plurality of battery performance data acquired using Electrochemical Impedance Spectroscopy (EIS), and (iv) a plurality of battery passport data; preprocess the plurality of aggregated data using one or more preprocessing techniques to obtain a plurality of preprocessed data; input the plurality of preprocessed data to an adaptive artificial intelligence (AI) model to obtain a plurality of trained data; extract a plurality of features from the plurality of trained data using one or more feature extraction techniques; identify a set of dominant features from the plurality of features based on a weighted score assigned to each of the plurality of features; and classify the set of dominant features from the plurality of features into at least one set of end-of-life (EoL) battery pathway category using a multi-criteria decision-making algorithm, wherein the multi-criteria decision-making algorithm determines an optimal EoL pathway category from a set of end-of life (EoL) battery pathway categories for each of the plurality of recyclable batteries when one or more predefined threshold conditions imposed on the set of dominant features are satisfied.

In yet another aspect, there are provided one or more non-transitory machine-readable information storage mediums comprising one or more instructions which when executed by one or more hardware processors cause: receiving a plurality of aggregated data pertaining a plurality of recyclable batteries in a battery sorting facility, wherein the plurality of aggregated data comprises at least (i) a plurality of diagnostic data acquired using one or more diagnostic tools, (ii) a plurality of vision data acquired using one or more image acquisition devices and one or more sensors, (ii) a plurality of battery performance data acquired using Electrochemical Impedance Spectroscopy (EIS), and (iv) a plurality of battery passport data; preprocessing the plurality of aggregated data using one or more preprocessing techniques to obtain a plurality of preprocessed data; inputting the plurality of preprocessed data to an adaptive artificial intelligence (AI) model to obtain a plurality of trained data; extracting a plurality of features from the plurality of trained data using one or more feature extraction techniques; identifying a set of dominant features from the plurality of features based on a weighted score assigned to each of the plurality of features; and classifying the set of dominant features from the plurality of features into at least one set of end-of-life (EoL) battery pathway category using a multi-criteria decision-making algorithm, wherein the multi-criteria decision-making algorithm determines an optimal EoL pathway category from the set of end-of life (EoL) battery pathway categories for each of the plurality of recyclable batteries when one or more predefined threshold conditions imposed on the set of dominant features are satisfied.

In accordance with an embodiment of the present disclosure, the set of EoL battery pathway categories comprises (i) a battery reuse, (ii) a battery remanufacture, (iii) a battery repurpose, (iv) a battery replacement, and (v) a battery recycle.

In accordance with an embodiment of the present disclosure, the one or more predefined threshold conditions imposed on the set of dominant features provide a correlation between each of (i) the plurality of diagnostic data, (ii) the plurality of vision data, (iii) the plurality of battery performance data, and (iv) the plurality of battery passport data.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this disclosure, illustrate exemplary embodiments and, together with the description, serve to explain the disclosed principles:

FIG. 1 illustrates an exemplary system for end-of-life (EoL) battery pathway categorization using a multi-criteria decision-making algorithm, according to some embodiments of the present disclosure.

FIG. 2, with reference to FIG. 1, illustrates an exemplary flow diagram illustrating a method for end-of-life (EoL) battery pathway categorization using a multi-criteria decision-making algorithm, using the system of FIG. 1, in accordance with some embodiments of the present disclosure.

### DETAILED DESCRIPTION

Exemplary embodiments are described with reference to the accompanying drawings. In the figures, the left-most digit(s) of a reference number identifies the figure in which the reference number first appears. Wherever convenient, the same reference numbers are used throughout the drawings to refer to the same or like parts. While examples and features of disclosed principles are described herein, modifications, adaptations, and other implementations are possible without departing from the scope of the disclosed embodiments. It is intended that the following detailed description be considered as exemplary only, with the true scope being indicated by the following embodiments described herein.

The global transition toward electric vehicles (EVs) is a pivotal step in achieving carbon neutrality and reducing reliance on fossil fuels. A robust circular economy for EV batteries is not just a sustainability goal but an economic and geopolitical necessity. The scarcity of critical metals and their uneven geographic distribution demand innovative solutions to maximize resource efficiency. Consequently, developing sustainable, scalable, and accurate methods to sort and manage EOL batteries is crucial to unlock a full value of a battery ecosystem while reducing environmental harm and mitigating economic inequalities. By implementing a systematic sorting process powered by advanced evaluation techniques and AI, retired EV batteries can be effectively categorized for remanufacturing, reuse, repurposing, replace, or recycling. Conventional methods struggle to accurately identify diverse battery chemistries and degradation levels, limiting reuse potential. The present disclosure addresses the unresolved problems of the conventional approaches by providing a comprehensive approach for sorting retired EV batteries into categories for remanufacturing, reuse, repurposing, or recycling that can enable a circular economy. This strategy not only reduces dependence on virgin material extraction but also minimizes waste and environmental risks, paving a way for a sustainable EV industry. The system of the present disclosure not only minimizes waste but also reduces reliance on virgin material extraction, mitigates environmental impact, and supports a sustainable EV industry. Moreover, it addresses geo-political vulnerabilities associated with critical metal supply chains, fostering economic resilience and equitable resource distribution. A well-executed circular economy framework for batteries is, therefore, a cornerstone of the global transition to clean energy.

Embodiments of the present disclosure provides a system and method for end-of-life (EoL) battery pathway categorization using a multi-criteria decision-making algorithm. The present disclosure provides a robust sorting mechanism for retired EV batteries, leveraging advanced evaluation techniques and artificial intelligence (AI) to ensure precise categorization. The system of the present disclosure is designed to evaluate battery health, identify potential applications for reuse, and recover valuable materials through recycling when necessary. The process is underpinned by three key evaluation techniques: X-Ray scanning, Electrochemical Impedance Spectroscopy (EIS), and Battery Management System (BMS) data analysis. These techniques ensure high sorting accuracy and help determine an optimal post-use category for each battery including at least a remanufacture, a reuse, a repurpose, or recycling.

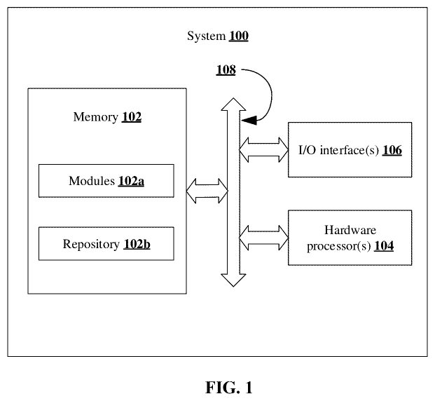

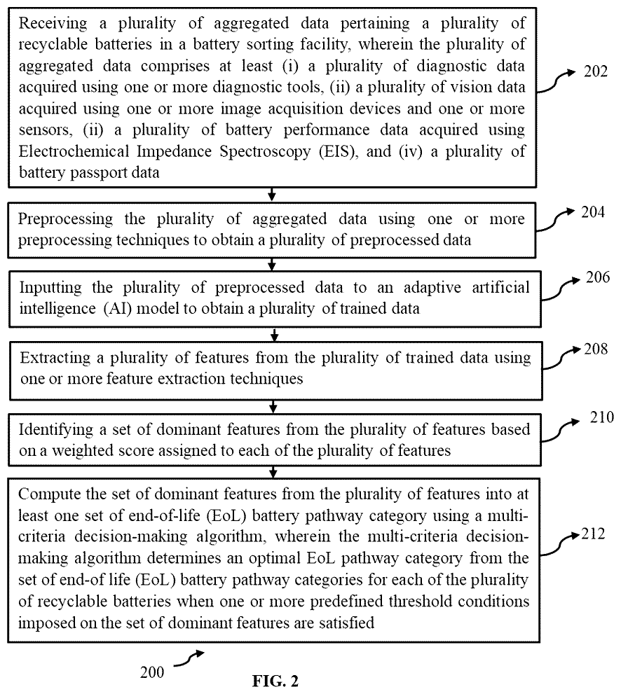

Referring now to the drawings, and more particularly to FIGS. 1 through 2, where similar reference characters denote corresponding features consistently throughout the figures, there are shown preferred embodiments and these embodiments are described in the context of the following exemplary system and/or method.

FIG. 1 illustrates an exemplary system for FIG. 1 illustrates an exemplary system for end-of-life (EoL) battery pathway categorization using a multi-criteria decision-making algorithm, according to some embodiments of the present disclosure. In an embodiment, the system 100 includes or is otherwise in communication with one or more hardware processors 104, communication interface device(s) or input/output (I/O) interface(s) 106, and one or more data storage devices or memory 102 operatively coupled to the one or more hardware processors 104. The one or more hardware processors 104, the memory 102, and the I/O interface(s) 106 may be coupled to a system bus 108 or a similar mechanism.

The I/O interface(s) 106 may include a variety of software and hardware interfaces, for example, a web interface, a graphical user interface, and the like. The I/O interface(s) 106 may include a variety of software and hardware interfaces, for example, interfaces for peripheral device(s), such as a keyboard, a mouse, an external memory, a plurality of sensor devices, a printer and the like. Further, the I/O interface(s) 106 may enable the system 100 to communicate with other devices, such as web servers and external databases.

The I/O interface(s) 106 can facilitate multiple communications within a wide variety of networks and protocol types, including wired networks, for example, local area network (LAN), cable, etc., and wireless networks, such as Wireless LAN (WLAN), cellular, or satellite. For the purpose, the I/O interface(s) 106 may include one or more ports for connecting a number of computing systems with one another or to another server computer. Further, the I/O interface(s) 106 may include one or more ports for connecting a number of devices to one another or to another server.

The one or more hardware processors 104 may be implemented as one or more microprocessors, microcomputers, microcontrollers, digital signal processors, central processing units, state machines, logic circuitries, and/or any devices that manipulate signals based on operational instructions. Among other capabilities, the one or more hardware processors 104 are configured to fetch and execute computer-readable instructions stored in the memory 102. In the context of the present disclosure, the expressions ‘processors’ and ‘hardware processors’ may be used interchangeably. In an embodiment, the system 100 can be implemented in a variety of computing systems, such as laptop computers, portable computer, notebooks, hand-held devices, workstations, mainframe computers, servers, a network cloud and the like.

The memory 102 may include any computer-readable medium known in the art including, for example, volatile memory, such as static random access memory (SRAM) and dynamic random access memory (DRAM), and/or non-volatile memory, such as read only memory (ROM), erasable programmable ROM, flash memories, hard disks, optical disks, and magnetic tapes. In an embodiment, the memory 102 includes a plurality of modules 102a and a repository 102b for storing data processed, received, and generated by one or more of the plurality of modules 102a. The plurality of modules 102a may include routines, programs, objects, components, data structures, and so on, which perform particular tasks or implement particular abstract data types.

The plurality of modules 102a may include programs or computer-readable instructions or coded instructions that supplement applications or functions performed by the system 100. The plurality of modules 102a may also be used as, signal processor(s), state machine(s), logic circuitries, and/or any other device or component that manipulates signals based on operational instructions. Further, the plurality of modules 102a can be used by hardware, by computer-readable instructions executed by the one or more hardware processors 104, or by a combination thereof. Further, the memory 102 may include information pertaining to input(s)/output(s) of each step performed by the processor(s) 104 of the system 100 and methods of the present disclosure.

The repository 102b may include a database or a data engine. Further, the repository 102b amongst other things, may serve as a database or includes a plurality of databases for storing the data that is processed, received, or generated as a result of the execution of the plurality of modules 102a. Although the repository 102b is shown internal to the system 100, it will be noted that, in alternate embodiments, the repository 102b can also be implemented external to the system 100, where the repository 102b may be stored within an external database (not shown in FIG. 1) communicatively coupled to the system 100. The data contained within such external database may be periodically updated. For example, new data may be added into the external database and/or existing data may be modified and/or non-useful data may be deleted from the external database. In one example, the data may be stored in an external system, such as a Lightweight Directory Access Protocol (LDAP) directory and a Relational Database Management System (RDBMS). In another embodiment, the data stored in the repository 102b may be distributed between the system 100 and the external database.

FIG. 2, with reference to FIG. 1, illustrates an exemplary flow diagram illustrating a method for end-of-life (EoL) battery pathway categorization using a multi-criteria decision-making algorithm, using the system of FIG. 1, in accordance with some embodiments of the present disclosure.

Referring to FIG. 2, in an embodiment, the system(s) 100 comprises one or more data storage devices or the memory 102 operatively coupled to the one or more hardware processors 104 and is configured to store instructions for execution of steps of the method by the one or more processors 104. The steps of the method 200 of the present disclosure will now be explained with reference to components of the system 100 of FIG. 1, the flow diagram as depicted in FIG. 2, and one or more examples. Although steps of the method 200 including process steps, method steps, techniques or the like may be described in a sequential order, such processes, methods and techniques may be configured to work in alternate orders. In other words, any sequence or order of steps that may be described does not necessarily indicate a requirement that the steps be performed in that order. The steps of processes described herein may be performed in any practical order. Further, some steps may be performed simultaneously, or some steps may be performed alone or independently.

In an embodiment, at step 202 of the present disclosure, one or more hardware processors 104 are configured to receive a plurality of aggregated data pertaining a plurality of batteries in a battery sorting facility. The plurality of aggregated data comprises at least (i) a plurality of diagnostic data acquired using one or more diagnostic tools, (ii) a plurality of vision data acquired using one or more image acquisition devices and one or more sensors, (iii) a plurality of battery performance data acquired using Electrochemical Impedance Spectroscopy (EIS), and (iv) a plurality of battery passport data. The one or more diagnostic tools may include but ae not limited to a battery management system (BMS) which is used to extract critical data points. The plurality of diagnostic data acquired using the one or more diagnostic tools may include but are not limited to metrics such as State of Health (SoH), State of Charge (SoC), cycle count, Depth of Discharge (DoD), charge-discharge profiles, impedance and internal resistance measurements, real time data collected using one or more IoT devices integrated with BMS, and/or the like. The plurality of diagnostic data is extracted and analyzed. The BMS data analysis complements physical and electrochemical assessments by providing a holistic view of battery's lifecycle, enabling accurate and data-driven decision-making. The plurality of vision data acquired using one or more image acquisition devices and one or more sensors may include but are not limited to high resolution images, thermal images providing signs of overheating or thermal runaway, videos, and/or the like that capture battery's external and internal condition. The one or more image acquisition devices may include but are not limited to high-resolution cameras, thermal imaging devices, 3D scanning systems, and/or the like. The one or more sensors may include but are not limited to X-ray scanning system or ultrasound system that are used for non-destructive internal inspection. Each retired battery undergoes a detailed X-Ray scan to capture high-resolution images of its internal structure. The scan identifies critical issues such as swelling, cracks, electrode misalignments, connector wear or terminal damage, and dendrite formations that could pose safety hazards or impair functionality using an artificial intelligence based model such as convolutional neural networks (CNNs). X-ray imaging results are used to eliminate batteries unsuitable for further use due to safety risks. This step ensures that severely damaged batteries are excluded early in the process, preventing unsafe reuse or repurpose and optimizing resource recovery during recycling.

In an embodiment, it is critical to perform electrochemical impedance spectroscopy (EIS) at a battery pack level, rather than at an individual cell level due to several practical, operational, and diagnostic reasons. The EIS provides real-world conditions and system-level insights, representative results, early fault detection in battery packs including cell imbalance identification, interconnect issues, and thermal effects. Further, the EIS provides scalability and efficiency in terms of practicality and time saving, ageing and degradation analysis, insights into pack design and thermal management, and use in predictive maintenance. The real-world conditions and system-level insights are provided by analyzing complete system behavior including the combined effects of the cells, interconnects, busbars, cooling system, and battery management system (BMS) by testing at the battery pack level. This is critical because a battery pack doesn't operate as isolated cells but as a unified energy storage system. Representative results include battery pack-level EIS that reflects the system's real-world impedance under actual working conditions, which is more relevant than cell-level data for operational scenarios. For early fault detection, cell imbalance identification, interconnect issues, and thermal effects are checked.
(i) Cell Imbalance Identification: Over time, differences in ageing and performance between cells in a battery pack lead to imbalance. Pack-level EIS can reveal such issues as variations in impedance across the cells manifest in overall impedance spectrum.
(ii) Interconnect Issues: High-frequency impedance can detect issues such as degraded welds, poor contact in busbars, or loose connectors, which cannot be identified through cell-level EIS.
(iii) Thermal Effects: Non-uniform heating in the battery pack can create impedance variations, which are detectable in a pack-level EIS, allows to pinpoint thermal hotspots or cooling inefficiencies.
   Scalability and efficiency are determined in terms of practicality and time saving
(i) Practicality: Testing individual cells in a battery pack is often impractical for large-scale energy storage systems or EV battery packs. Pack-level EIS reduces the need for disassembly and simplifies the process.
(ii) Time saving: For gigawatt-scale systems or EV packs with thousands of cells, cell-level testing would be time-prohibitive. Pack-level EIS offers a faster alternative without compromising much on diagnostic capabilities.
   For ageing and degradation analysis, collective aging effects and localized issues are analyzed.
(i) Collective Aging Effects: Impedance changes at the battery pack level reflect the cumulative effects of aging and degradation across all cells. This provides an overall state of health (SOH) for the pack and can highlight significant deviations from baseline values.
(ii) Localized Issues: Pack-level EIS may reveal localized problems (e.g., a degraded cell or parallel group) as anomalies in the impedance spectrum, which can guide further investigations.
   For insights into pack design and thermal management, validation of design and temperature-dependent analysis is performed.
(i) Validation of Design: Impedance spectroscopy at the battery pack level helps validate design of electrical and thermal systems, including arrangement of cells and current pathways. It ensures that the battery pack performs as expected under different frequencies and operational conditions.
(ii) Temperature-Dependent Analysis: EIS performed at different temperatures can assess the battery pack's thermal management effectiveness. Impedance variations across the battery pack can indicate insufficient cooling in specific areas.
   For use in predictive maintenance, condition monitoring and end-of-life prediction are performed.
(i) Condition Monitoring: Pack-level EIS enables tracking of impedance changes over time, providing a non-invasive tool for monitoring the battery pack's health and predicting failures before they occur.
(ii) End-of-Life Prediction: By comparing pack-level impedance with established thresholds or historical data, it's possible to predict the remaining useful life (RUL) of the battery pack.
   While pack-level EIS provides many advantages, it also comes with challenges:
(i) Data Interpretation: Deconvoluting pack-level impedance into meaningful insights about individual cells or groups requires advanced algorithms and modeling.
(ii) BMS Interference: The BMS may influence EIS results, so configurations or bypass strategies may be necessary during testing.
(iii) Resolution: Fine details about individual cell performance may be lost, so the method works best when supported by occasional cell-level analysis for calibration.

The plurality of battery performance data acquired using Electrochemical Impedance Spectroscopy (EIS) is used to evaluate internal resistance and Remaining Useful Life (RUL) of the battery. The plurality of batteries are connected to an EIS equipment which measures their impedance across a range of frequencies. Results obtained from EIS provide insights into the battery's internal resistance and electrochemical behavior, which are critical in determining its remaining capacity and performance. The plurality of battery performance data comprise but are not limited to values of ohmic resistance, charge transfer resistance, frequency, diffusion impedance (also known as Warburg impedance), real impedance, imaginary impedance, phase angle, pack-to-pack variation, cell-to-cell imbalance, high-frequency noise or anomalies, state-of-health (SOH) indicators, and/or the like. In an embodiment, a threshold value or a threshold range is assigned to each of the plurality of battery performance data. The ohmic resistance represents an internal resistance of an entire battery pack including cell internal resistance, busbars, connectors, and interconnects. For a new battery pack, the threshold value (i.e., baseline) for Ohmic resistance should be low and consistent with the pack's design specifications. Typical values for lithium-ion battery packs: <10 mΩ (for EV packs, may vary based on pack size). The charge transfer resistance is related to electrochemical reactions at electrodes. An increase signifies aging, solid electrolyte interphase (SEI) layer growth, or active material loss. The threshold values for Charge Transfer Resistance vary but typically range from 10-50 mΩ depending on chemistry and pack configuration. The diffusion impedance reflects ion diffusion limitations within the electrodes and electrolyte. For diffusion Impedance, a linear Warburg region at low frequencies (slope ~45° in Nyquist plot) is expected and used as threshold. The real impedance represents a combined measure of all resistances. The phase angle indicates the balance between resistive and reactive components. A healthy battery pack shows consistent phase angles at specific frequencies based on design. The pack-to-pack variation indicates that variability in impedance between packs should be minimal. Threshold value for the pack-to-pack variation in or across the battery packs is less than x % (e.g., say x=10). The cell-to-cell imbalance represents that the presence of imbalanced cells affects overall impedance while EIS tests the battery pack as a whole. The threshold value of the cell-to-cell imbalance in or should not cause impedance to deviate significantly from baseline values. The high-frequency noise or anomalies data may reveal issues with connectors, wiring, or interconnects. Threshold value of the noise in the high-frequency region should be minimal. In an embodiment, the state-of-health (SOH) indicators are derived directly from EIS testing also. A threshold value of SOH>y % (e.g., y=80) is considered acceptable for EV applications.

For Electrochemical Impedance Spectroscopy (EIS) on a battery pack, threshold values for acceptance or rejection of the battery pack depend on the battery chemistry, design, application, and operating conditions. Rejection criteria for a battery pack states that the battery pack fails EIS testing if the following conditions are satisfied:
(i) The ohmic resistance exceeds a baseline by >20-50%.
(ii) Impedance magnitude deviates significantly at critical frequencies.
(iii) Phase angle or Warburg impedance shows unexpected behavior.
(iv) High-frequency noise suggests design or connection issues.
(v) SOH drops below the application-specific threshold (e.g., <80% for EVs).
   Application-specific criteria for EV Battery Pack is that they require low internal resistance for high-power applications and thresholds are stricter to ensure performance under load. Application-specific criteria for stationary energy storage systems (BESS) is that higher resistance may be acceptable if capacity and efficiency remain stable.

In an embodiment, a graphical representation used in Electrochemical Impedance Spectroscopy (EIS) to analyze the complex impedance of an electrochemical system is provided as a Nyquist plot. In mathematical terms, it is a plot of the imaginary part of impedance versus the real part of impedance, where each point corresponds to a specific frequency of the applied Alternate Current (AC) signal. Mathematical representation of the total impedance (Z) in an EIS test is a complex number, expressed as equation (1):

$$Z ( ω ) = {Z}^{′} ( ω ) + {jZ}^{″} ( ω ) \qquad ( 1 )$$

Here, Z′(ω) represents the real part of impedance, representing resistive behavior and jZ″(ω) represents the imaginary part of impedance, representing capacitive or inductive behavior, j represents imaginary unit (j=✓−1), ω represents angular frequency of the AC signal and provided as ω=2Πf. In the Nyquist plots, X-axis represents Z′(ω), Y-axis represents Z″(ω), and each point on the curve of the Nyquist plots corresponds to a different frequency of the AC signal. Higher frequencies are closer to the origin, and lower frequencies extend farther along the curve. The shape of the Nyquist plot provides insight into electrochemical system's properties. For example, a semi-circle in the Nyquist plot is typical for systems with a single charge-transfer resistance and a double-layer capacitance. Diameter of the semi-circle represents. Low-frequency tail in the Nyquist plot represents diffusion effects (Warburg impedance) in systems where ion transport is involved. Multiple semi-circles indicate a presence of multiple processes such as charge transfer, diffusion, and reaction kinetics.

In an embodiment, the plurality of battery passport data includes but is not limited to historical data such as repair history, cycles completed, and/or the like. The historical data provides additional context for predicting future performance and safe usage scenarios. Battery passports are often utilized solely for traceability, with no active role in sorting processes. The plurality of diagnostic data, the plurality of vision data, the plurality of battery performance data, and the plurality of battery passport data is combined or integrated to provide the plurality of aggregated data.

At step 204 of the present disclosure, the one or more hardware processors 104 are configured to preprocess the plurality of aggregated data using one or more preprocessing techniques to obtain a plurality of preprocessed data. The one or more preprocessing techniques include but are not limited to normalization of impedance values such as real impedance values and the imaginary impedance values across frequency ranges for consistency, handling missing or noisy data using interpolation and filtering techniques, cleaning methods, providing label datasets with outcomes like SOH or Remaining Useful Life (RUL), and/or the like.

At step 206 of the present disclosure, the one or more hardware processors 104 are configured to input the plurality of preprocessed data to an adaptive artificial intelligence (AI) model to obtain a plurality of trained data. The adaptive artificial intelligence (AI) model comprises but are not limited to supervised models such as neural network models and regression models implemented using random forest or gradient boosting algorithms, semi-supervised models, time series models such as long-short term memory (LSTM) or Autoregressive Integrated Moving Average (ARIMA) for trend predictions of impedance growth and RUL estimation, and unsupervised models such as clustering models to detect anomalies in impedance behavior.

At step 208 of the present disclosure, the one or more hardware processors 104 are configured to extract a plurality of features from the plurality of trained data using one or more feature extraction techniques. The one or more feature extraction techniques may include but are not limited to time-domain analysis, frequency-domain analysis using Fourier Transform, statistical methods such as mean, variance, skewness, and kurtosis, machine learning-based feature selection methods such as Principal Component Analysis (PCA), and autoencoders based methods to identify most relevant parameters indicative of battery health and remaining useful life. The plurality of features may include but are not limited to nyquist arc radius (related to charge transfer resistance), equivalent circuit model (ECM) parameters, growth rate of SEI resistance, Nyquist plot deviations over cycles slope of the Warburg region, peak phase angle from bode plots, structural damage scaled scores from X-Ray imaging for physical defects, predefined thresholds for each category as training labels, battery health features such as SOH and other health indicators from BMS data, electrical performance such as impedance and RUL from EIS testing, damage severity scores, and/or the like. In an embodiment, domain knowledge is used to to engineer features such as the damage severity scores.

At step 210 of the present disclosure, the one or more hardware processors 104 are configured to identify a set of dominant features from the plurality of features based on a weighted score assigned to each of the plurality of features. In an embodiment, the set of dominant features are identified based on a weighted importance score assigned to each of the the plurality of features based on their relevance to battery performance and safety, and significance in determining battery usability. The weighted importance score for each feature is assigned using a combination of statistical, heuristic, and machine learning-based methods. Feature importance can be determined using techniques such as SHAP (Shapley Additive Explanations) values, which quantify contribution of each feature to model predictions, or permutation importance. This measures an impact of randomly shuffling values of a feature. Additionally, model-specific methods such as Gini importance in decision trees, coefficient magnitudes in linear regression, or attention mechanisms in deep learning models are alternatively used. Final weight assignment is performed based on the correlation of each feature with key battery performance indicators such as capacity retention, internal resistance growth, and thermal stability, ensuring that the most critical features for predicting battery health and safety are prioritized. The features having high weighted importance score are comprised in the set of dominant features. The set of dominant features can be alternatively referred as ‘important features’ and ‘critical features’. For example, structural damage severity may have 40% weight, RUL (EIS) may have 35% weight, and SOH (BMS) may have 25% weight.

At step 212 of the present disclosure, the one or more hardware processors 104 are configured to classify the set of dominant features from the plurality of features into at least one set of end-of-life (EoL) battery pathway category using a multi-criteria decision-making algorithm. The set of EoL battery pathway categories comprises (i) a battery reuse, (ii) a battery remanufacture, (iii) a battery repurpose, (iv) a battery replacement, and (v) a battery recycle. The multi-criteria decision-making algorithm determines an optimal EoL pathway category from the set of end-of-life (EoL) battery pathway categories for each of the plurality of recyclable batteries when one or more predefined threshold conditions imposed on the set of dominant features are satisfied. For example, a battery with different predefined threshold conditions on the SOH received from BMS data is eligible to be categorized into different set of EoL battery pathway categories as shown below:
SOH>90%: Eligible for Remanufacture.
SOH 80-90%: Eligible for Reuse.
SOH 50-80%: Eligible for Repurpose.
SOH<50%: Sorted for Recycling.
   The one or more predefined threshold conditions imposed on the set of dominant features provide a correlation between each of (i) the plurality of diagnostic data, (ii) the plurality of vision data, (iii) the plurality of battery performance data, and (iv) the plurality of battery passport data. The plurality of vision data (i.e., visual inspection results) are correlated with the plurality of diagnostic data, the plurality of battery performance data, and the plurality of battery passport data to validate findings. For example, if SOH is high but external damage is detected, a battery remanufacture is recommended. However, if severe physical damage is present, the battery is classified as to be recycled.

The adaptive AI model outputs a most suitable end-of-life (EoL) battery pathway category for a battery based on the classification. For example,

output: Battery X→Reuse(Confidence Score: 92%)

A confidence score accompanies each classification, indicating the certainty of the prediction. In an embodiment, the adaptive artificial intelligence (AI) model is dynamically updated in real time for a plurality of incoming aggregated data. In an embodiment, the plurality of aggregated data is split into training and validation sets and the adaptive AI model is tested on unseen data to measure accuracy and confidence levels. As more data is collected, the adaptive AI model learns and improves its accuracy, refining the sorting process over time. The hyperparameters of the Adaptive AI model are tuned to maximize sorting accuracy and explainable AI (XAI) techniques are incorporated for interpretability and transparency.

Batteries with poor results proceed to recycling. EIS testing enables precise classification of batteries based on their remaining performance potential, ensuring optimal allocation to suitable applications and minimizing resource wastage. Batteries with low internal resistance and high RUL are sorted for Remanufacture or Reuse, while those with moderate RUL are earmarked for Repurpose. In an example scenario, a battery is inspected and found to have no visible external damage. The X-Ray scan detects no cracks or swelling. EIS testing reveals an internal resistance of 5 mΩ and an RUL of 85%. BMS data shows an SOH of 88% and 450 cycles completed. The adaptive AI model processes this data and classifies the battery as suitable for Reuse, with a confidence score of 95%. By combining robust evaluation techniques such as using diagnostic tool, EIS, BMS, Battery passport, and vision systems with an adaptive AI model, the system 100 of the present disclosure ensures precise and efficient sorting of retired EV batteries into the correct post-use categories, ultimately supporting sustainability and circular economy goals. Thus, misclassification (e.g., sending reusable batteries for recycling) is minimized/reduced by combining internal and external assessments. The system of the present disclosure provides scalability by handling large volumes of batteries efficiently, consistency by reducing variability caused by human judgment, continuous learning where the adaptive AI model improves over time as more data is collected, refining decision-making capabilities, and transparency where with explainable AI, stakeholders can understand how decisions are made.

The written description describes the subject matter herein to enable any person skilled in the art to make and use the embodiments. The scope of the subject matter embodiments is defined herein and may include other modifications that occur to those skilled in the art. Such other modifications are intended to be within the scope of the present disclosure if they have similar elements that do not differ from the literal language of the embodiments or if they include equivalent elements with insubstantial differences from the literal language of the embodiments described herein.

It is to be understood that the scope of the protection is extended to such a program and in addition to a computer-readable means having a message therein; such computer-readable storage means contain program-code means for implementation of one or more steps of the method, when the program runs on a server or mobile device or any suitable programmable device. The hardware device can be any kind of device which can be programmed including e.g., any kind of computer like a server or a personal computer, or the like, or any combination thereof. The device may also include means which could be e.g., hardware means like e.g., an application-specific integrated circuit (ASIC), a field-programmable gate array (FPGA), or a combination of hardware and software means, e.g., an ASIC and an FPGA, or at least one microprocessor and at least one memory with software processing components located therein. Thus, the means can include both hardware means and software means. The method embodiments described herein could be implemented in hardware and software. The device may also include software means. Alternatively, the embodiments may be implemented on different hardware devices, e.g., using a plurality of CPUs.

The embodiments herein can comprise hardware and software elements. The embodiments that are implemented in software include but are not limited to, firmware, resident software, microcode, etc. The functions performed by various components described herein may be implemented in other components or combinations of other components. For the purposes of this description, a computer-usable or computer readable medium can be any apparatus that can comprise, store, communicate, propagate, or transport the program for use by or in connection with the instruction execution system, apparatus, or device.

The illustrated steps are set out to explain the exemplary embodiments shown, and it should be anticipated that ongoing technological development will change the manner in which particular functions are performed. These examples are presented herein for purposes of illustration, and not limitation. Further, the boundaries of the functional building blocks have been arbitrarily defined herein for the convenience of the description. Alternative boundaries can be defined so long as the specified functions and relationships thereof are appropriately performed. Alternatives (including equivalents, extensions, variations, deviations, etc., of those described herein) will be apparent to persons skilled in the relevant art(s) based on the teachings contained herein. Such alternatives fall within the scope of the disclosed embodiments. Also, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items. It must also be noted that as used herein, the singular forms “a,” “an,” and “the” include plural references unless the context clearly dictates otherwise.

Furthermore, one or more computer-readable storage media may be utilized in implementing embodiments consistent with the present disclosure. A computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., be non-transitory. Examples include random access memory (RAM), read-only memory (ROM), volatile memory, nonvolatile memory, hard drives, CD ROMs, DVDs, flash drives, disks, and any other known physical storage media.

It is intended that the disclosure and examples be considered as exemplary only, with a true scope of disclosed embodiments being indicated herein by the following claims.

What is claimed is:

1. A processor implemented method, comprising:
receiving, via one more hardware processors, a plurality of aggregated data pertaining a plurality of recyclable batteries in a battery sorting facility, wherein the plurality of aggregated data comprises at least (i) a plurality of diagnostic data acquired using one or more diagnostic tools, (ii) a plurality of vision data acquired using one or more image acquisition devices and one or more sensors, (ii) a plurality of battery performance data acquired using Electrochemical Impedance Spectroscopy (EIS), and (iv) a plurality of battery passport data;
preprocessing, via the one more hardware processor, the plurality of aggregated data using one or more preprocessing techniques to obtain a plurality of preprocessed data;
inputting, via the one more hardware processor, the plurality of preprocessed data to an adaptive artificial intelligence (AI) model to obtain a plurality of trained data;
extracting, via the one more hardware processors, a plurality of features from the plurality of trained data using one or more feature extraction techniques;
identifying, via the one more hardware processors, a set of dominant features from the plurality of features based on a weighted score assigned to each of the plurality of features; and
classifying, via the one more hardware processors, the set of dominant features from the plurality of features into at least one set of end-of-life (EoL) battery pathway category using a multi-criteria decision-making algorithm, wherein the multi-criteria decision-making algorithm determines an optimal EoL pathway category from the set of end-of life (EoL) battery pathway categories for each of the plurality of recyclable batteries when one or more predefined threshold conditions imposed on the set of dominant features are satisfied.

2. The processor implemented method of claim 1, wherein the set of EoL battery pathway categories comprises (i) a battery reuse, (ii) a battery remanufacture, (iii) a battery repurpose, (iv) a battery replacement, and (v) a battery recycle.

3. The processor implemented method of claim 1, wherein the one or more predefined threshold conditions imposed on the set of dominant features provide a correlation between each of (i) the plurality of diagnostic data, (ii) the plurality of vision data, (iii) the plurality of battery performance data, and (iv) the plurality of battery passport data.

4. A system, comprising:
a memory storing instructions;
one or more communication interfaces; and
one or more hardware processors coupled to the memory via the one or more communication interfaces, wherein the one or more hardware processors are configured by the instructions to:
receive a plurality of aggregated data pertaining a plurality of recyclable batteries in a battery sorting facility, wherein the plurality of aggregated data comprises at least (i) a plurality of diagnostic data acquired using one or more diagnostic tools, (ii) a plurality of vision data acquired using one or more image acquisition devices and one or more sensors, (ii) a plurality of battery performance data acquired using Electrochemical Impedance Spectroscopy (EIS), and (iv) a plurality of battery passport data;
preprocess the plurality of aggregated data using one or more preprocessing techniques to obtain a plurality of preprocessed data;
input the plurality of preprocessed data to an adaptive artificial intelligence (AI) model to obtain a plurality of trained data;
extract a plurality of features from the plurality of trained data using one or more feature extraction techniques;
identify a set of dominant features from the plurality of features based on a weighted score assigned to each of the plurality of features; and
classify the set of dominant features from the plurality of features into at least one set of end-of-life (EoL) battery pathway category using a multi-criteria decision-making algorithm, wherein the multi-criteria decision-making algorithm determines an optimal EoL pathway category from a set of end-of life (EoL) battery pathway categories for each of the plurality of recyclable batteries when one or more predefined threshold conditions imposed on the set of dominant features are satisfied.

5. The system of claim 4, wherein the set of EoL battery pathway categories comprises (i) a battery reuse, (ii) a battery remanufacture, (iii) a battery repurpose, (iv) a battery replacement, and (v) a battery recycle.

6. The system of claim 4, wherein the one or more predefined threshold conditions imposed on the set of dominant features provide a correlation between each of (i) the plurality of diagnostic data, (ii) the plurality of vision data, (iii) the plurality of battery performance data, and (iv) the plurality of battery passport data.

7. One or more non-transitory machine-readable information storage mediums comprising one or more instructions which when executed by one or more hardware processors cause:
receiving a plurality of aggregated data pertaining a plurality of recyclable batteries in a battery sorting facility, wherein the plurality of aggregated data comprises at least (i) a plurality of diagnostic data acquired using one or more diagnostic tools, (ii) a plurality of vision data acquired using one or more image acquisition devices and one or more sensors, (ii) a plurality of battery performance data acquired using Electrochemical Impedance Spectroscopy (EIS), and (iv) a plurality of battery passport data;
preprocessing the plurality of aggregated data using one or more preprocessing techniques to obtain a plurality of preprocessed data;
inputting the plurality of preprocessed data to an adaptive artificial intelligence (AI) model to obtain a plurality of trained data;
extracting a plurality of features from the plurality of trained data using one or more feature extraction techniques;
identifying a set of dominant features from the plurality of features based on a weighted score assigned to each of the plurality of features; and
classifying the set of dominant features from the plurality of features into at least one set of end-of-life (EoL) battery pathway category using a multi-criteria decision-making algorithm, wherein the multi-criteria decision-making algorithm determines an optimal EoL pathway category from the set of end-of life (EoL) battery pathway categories for each of the plurality of recyclable batteries when one or more predefined threshold conditions imposed on the set of dominant features are satisfied.

8. The one or more non-transitory machine readable information storage mediums of claim 7, wherein the set of EoL battery pathway categories comprises (i) a battery reuse, (ii) a battery remanufacture, (iii) a battery repurpose, (iv) a battery replacement, and (v) a battery recycle.

9. The one or more non-transitory machine readable information storage mediums of claim 7, wherein the one or more predefined threshold conditions imposed on the set of dominant features provide a correlation between each of (i) the plurality of diagnostic data, (ii) the plurality of vision data, (iii) the plurality of battery performance data, and (iv) the plurality of battery passport data.
